(19) United States
(12) Patent Application Publication
(10) Pub. No.: US 2017/0012177 A1
(43) Pub. Date: Jan. 12, 2017

(54) LED BASED LIGHTING SYSTEM

(71) Applicant: Cree, Inc., Durham, NC (US)

(72) Inventor: Troy A. Trottier, Cary, NC (US)

(21) Appl. No.: 14/794,884

(22) Filed: Jul. 9, 2015

(51) Int. Cl. H01L 33/48; H01L 33/62; H01L 33/56; H01L 27/15

(52) U.S. Cl. CPC H01L 33/483; H01L 27/153; H01L 33/62; H01L 33/56

(57) ABSTRACT

An LED lamp includes a base connected to an optically transmissive enclosure. An LED assembly for emitting light when energized through an electrical path is in the enclosure. The LED assembly comprises a LED array in a tube and a fill material filling the tube. An optic element comprising at least one LED assembly defines a lighted member in the enclosure. The fill material may include combinations of an encapsulant, a phosphor and a thermally conductive material.

### BACKGROUND

Light emitting diode (LED) lighting systems are becoming prevalent as replacements for older legacy lighting systems. LED systems are an example of solid state lighting (SSL) and have advantages over legacy lighting solutions, such as incandescent and fluorescent lighting, because they use less energy, are more durable, operate longer, can be combined in multi-color arrays that can be controlled to deliver virtually any color light, and generally contain no lead or mercury. A solid-state lighting system may take the form of a lighting unit, light fixture, light bulb, or a lamp (hereinafter “lamp”).

An LED lamp may include, for example, a packaged light emitting device including one or more light emitting diodes (LEDs), which may include inorganic LEDs, which may include semiconductor layers forming p-n junctions and/or organic LEDs, which may include organic light emission layers. Light perceived as white or near-white may be generated by a combination of red, green, and blue (“RGB”) LEDs. Output color of such a device may be altered by separately adjusting the supply of current to the red, green, and blue LEDs. Another method for generating white or near-white light is by using a lumiphor such as a phosphor. Still another approach for producing white light is to stimulate phosphors or dyes of multiple colors with an LED source. Many other approaches can be taken.

One type of legacy lighting system is an incandescent bulb that typically comprises a wire filament or filaments supported in a glass enclosure. Wires extend between the bulb's Edison screw base and the filament to provide electric current from the bulb's base to the filament. The filament heats and glows to emit usable light. In an incandescent bulb the base is typically connected to an enclosure where the enclosure may have a variety of shapes and sizes.

### SUMMARY

In some embodiments an LED lamp comprises an enclosure and an optic element in the enclosure. The optic element comprises an LED array for emitting light when energized through an electrical path and a tube surrounding the LED array with a fill material in the tube. A base is connected to the enclosure where the base may be in the electrical path. The fill material may comprise an optically transparent encapsulant. The encapsulant may comprise silicone. The optic element may be configured to visually appear like one of a cage, a loop, and a linear filament. The fill material may comprise an encapsulant and a phosphor. The fill material may comprise an encapsulant and a thermally conductive material. The fill material may comprise an encapsulant, a thermally conductive material and a phosphor. The LED array may comprise a LED mounted on a transparent substrate. The LED array may comprise a plurality of LEDs connected by wirebonds. The fill material may comprise a thermal powder and an encapsulant. The fill material may be exposed at an end of the tube. The fill material may be thermally coupled to a heat sink.

In some embodiments a LED lamp comprises a base and an enclosure connected to the base. An optic element is in the enclosure and comprises a LED assembly comprising a LED array for emitting light when energized through an electrical path and a tube surrounding the LED array with a fill material filling the tube.

The fill material may comprise an optically transparent encapsulant. The optic element may be configured to visually appear like one of a cage, a loop, and a linear filament. The fill material may comprise at least one of an encapsulant, a phosphor and a thermally conductive material. The LED assembly may comprise a LED mounted on a substrate. The substrate may be transparent.

### BRIEF DESCRIPTION OF THE DRAWINGS

FIG. 1 is a side view of an embodiment of a LED lamp of the invention.

FIG. 2 is a vertical section view of an alternate embodiment of a LED lamp of the invention.

FIG. 3 is a section view of an embodiment of a LED assembly used in the lamp of the invention.

FIG. 4 is a perspective view of the LED assembly of FIG. 3.

FIG. 5 is a section view of another embodiment of a LED assembly used in the lamp of the invention.

FIG. 6 is a perspective view of the LED assembly of FIG. 5.

FIG. 7 is a side view of another embodiment of a LED lamp of the invention.

FIG. 8 is a vertical section view of an alternate embodiment of a LED lamp of the invention.

FIG. 9 is a section view of another embodiment of a LED assembly used in the lamp of the invention.

FIG. 10 is a section view of another embodiment of a LED assembly used in the lamp of the invention.

FIG. 11 is a section view of another embodiment of a LED assembly used in the lamp of the invention.

FIG. 12 is a section view of another embodiment of a LED assembly used in the lamp of the invention

FIG. 13 is a section view of another embodiment of a LED assembly used in the lamp of the invention.

FIG. 14 is a section view of another embodiment of a LED assembly used in the lamp of the invention.

FIG. 15 is a vertical section view of an alternate embodiment of a LED lamp of the invention.

### DETAILED DESCRIPTION

Embodiments of the present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer or region to another element, layer or region as illustrated in the figures. It will be understood that these terms are intended to encompass different orientations of the device in addition to the orientation depicted in the figures.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

Unless otherwise expressly stated, comparative, quantitative terms such as “less” and “greater”, are intended to encompass the concept of equality. As an example, “less” can mean not only “less” in the strictest mathematical sense, but also, “less than or equal to.”

The terms “LED” and “LED device” as used herein may refer to any solid-state light emitter. The terms “solid state light emitter” or “solid state emitter” may include a light emitting diode, laser diode, organic light emitting diode, and/or other semiconductor device which includes one or more semiconductor layers, which may include silicon, silicon carbide, gallium nitride and/or other semiconductor materials, a substrate which may include sapphire, silicon, silicon carbide and/or other microelectronic substrates, and one or more contact layers which may include metal and/or other conductive materials. A solid-state lighting device produces light (ultraviolet, visible, or infrared) by exciting electrons across the band gap between a conduction band and a valence band of a semiconductor active (light-emitting) layer, with the electron transition generating light at a wavelength that depends on the band gap. Thus, the color (wavelength) of the light emitted by a solid-state emitter depends on the materials of the active layers thereof. In various embodiments, solid-state light emitters may have peak wavelengths in the visible range and/or be used in combination with lumiphoric materials having peak wavelengths in the visible range. Multiple solid state light emitters and/or multiple lumiphoric materials (i.e., in combination with at least one solid state light emitter) may be used in a single device, such as to produce light perceived as white or near white in character. In certain embodiments, the aggregated output of multiple solid-state light emitters and/or lumiphoric materials may generate warm white light output having a color temperature range of from about 2200K to about 6000K.

Solid state light emitters may be used individually or in combination with one or more lumiphoric materials (e.g., phosphors, scintillators, lumiphoric inks) and/or optic elements to generate light at a peak wavelength, or of at least one desired perceived color (including combinations of colors that may be perceived as white). Inclusion of lumiphoric (also called ‘luminescent’) materials in lighting devices as described herein may be accomplished by direct coating on solid state light emitter, adding such materials to encapsulants, adding such materials to lenses, by embedding or dispersing such materials within lumiphor support elements, and/or coating such materials on lumiphor support elements. Other materials, such as light scattering elements (e.g., particles) and/or index matching materials, may be associated with a lumiphor, a lumiphor binding medium, or a lumiphor support element that may be spatially segregated from a solid state emitter.

It should also be noted that the term “lamp” is meant to encompass not only a solid-state replacement for a traditional incandescent bulb, a fluorescent bulb, a complete fixture, as illustrated herein, but also a replacement for any type of light fixture that may be designed as a solid state fixture.

In a traditional incandescent bulb a filament, such as a tungsten filament, may be supported by support wires secured to or embedded in a glass stem where the stem extends from the bulb base into an optically transmissive enclosure such as a glass globe. In a typical modern bulb, the support wires position the filament at the approximate center of the enclosure such that the filament extends generally transversely to the longitudinal axis of the bulb. The light is projected substantially uniformly over the surface of the enclosure, although some variation in the dispersion of light over the surface area of the enclosure may occur. In other Edison style incandescent bulbs the filament may assume a variety of shapes within the enclosure. In vintage incandescent bulbs and in some modern incandescent bulbs designed to mimic vintage bulbs, the filament may assume more complex shapes within the enclosure. For example multiple glowing filaments may be provided that extend in a variety of patterns. Such filaments may assume a variety of shapes such as multiple loops, cage style, spiral, hairpin or the like. In traditional incandescent bulbs current is delivered to the filament or filaments by electrical wires that extend from the electrically conductive base and are connected to the filament(s). The electrical wires may also serve as the physical support for the filament(s). Electrical current is passed through the filament(s) causing the filament to heat and produce visible light. The filament(s) may be visible during operation of the bulb as a glowing component, especially when the bulb is dimmed. When low current is passed through the filament, such as in a dimmer application, the filament may glow as yellow-orange-red light.

The LED lamp of the invention uses an LED light source in a lamp that has the visual appearance of a traditional incandescent bulb. In some embodiments, a lamp having a connector such as an Edison screw may be connected to a source of power, such as an Edison socket. The Edison screw may both provide the physical connection between the lamp and the fixture and form part of the electrical path for providing current from a power source to the LEDs. In other embodiments the lamp may comprise an LED light source connected to a bayonet-style base that may be inserted into a bayonet-style socket. In a bayonet-style connector the lamp base comprises external lugs where the base and socket are configured to correspond to, and to have the external appearance of, standard bayonet connectors. Typically, in a standard bayonet connector the base is inserted into the socket and is rotated a partial turn to engage the lugs with lug receptacles in the socket. Standard bayonet connectors come in a variety of sizes. The bayonet connector may both provide the physical connection between the lamp and the fixture and form part of the electrical path for providing current from a power source to the LEDs. The lamp comprises an internal optic element that is configured such that the optic element emits light in a visible pattern that has a visual appearance that mimics the light pattern emitted by a glowing incandescent filament of a traditional incandescent bulb. The optically transmissive enclosure and base including an Edison screw, bayonet connector or other type of connector may be provided in a variety of sizes and shapes.

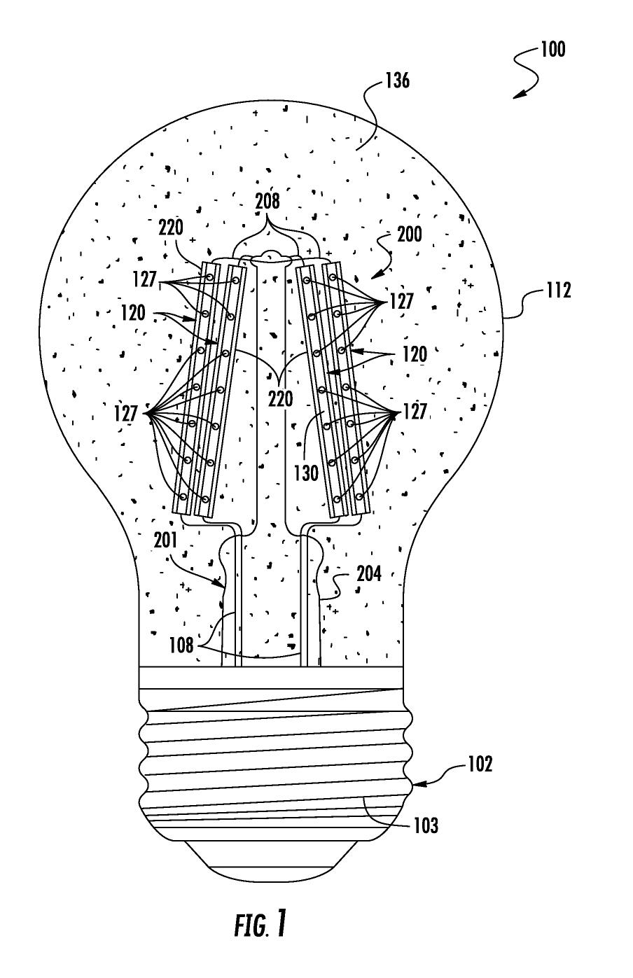

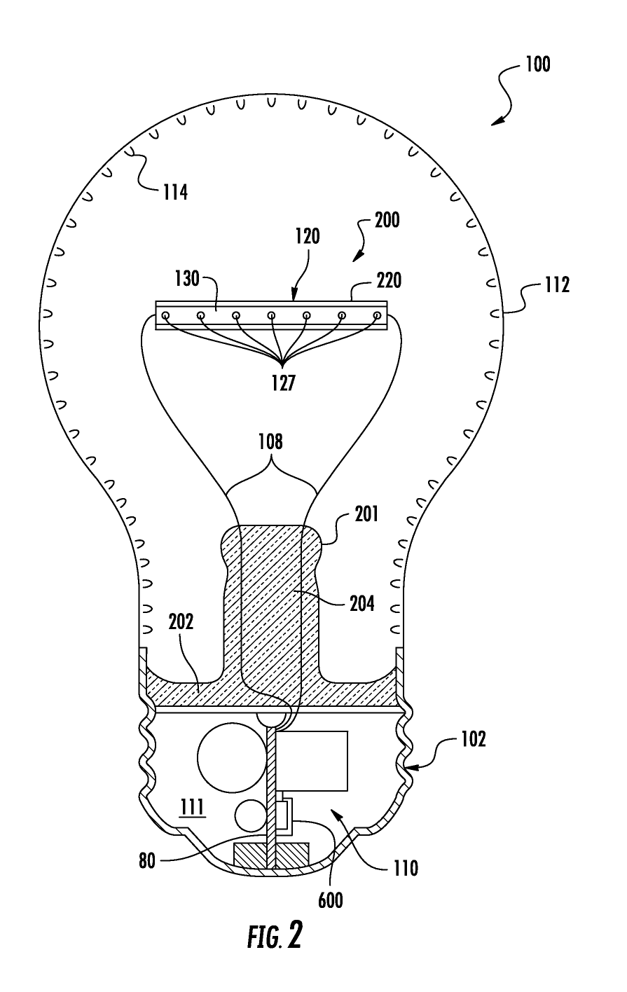

Referring to FIGS. 1 and 2 a lamp 100 according to some embodiments of the present invention is shown. Lamp 100 is shown having a form factor that may correspond to an incandescent bulb, such as an A-series bulb, or similar style bulb with a base 102 and an optically transmissive enclosure 112. Lamp 100 may be designed to serve as a solid-state replacement for an incandescent bulb. Lamp 100 may have other form factors and may also have the size and form factor of a smaller incandescent candelabra bulb, such as that commonly used in appliances, ceiling fans, chandeliers or the like or of larger bulbs. The lamp 100 may conform to other standards or to other non-standard bulb form factors. Because the lamp 100 of the invention may be advantageously used to mimic the visual appearance of an illuminated traditional or vintage bulbs (hereinafter “traditional bulbs”) the enclosure 112 may have a shape that conforms to traditional bulbs including globe, tube, or the like. The enclosure 112 is, in some embodiments, a transparent enclosure of similar shape to that commonly used in traditional incandescent bulbs. The enclosure may be formed of glass, polycarbonate or other optically transmissive material. In some embodiments, the enclosure 112 may be coated on the inside with silica or other diffuser 114, providing a diffuse scattering layer that produces a more uniform far field pattern. It should also be noted that in this or any of the embodiments shown here, the optically transmissive enclosure 112 or a portion of the optically transmissive enclosure could be coated or impregnated with phosphor. Because the lamp as described herein may be used to mimic the appearance of traditional incandescent bulbs, including vintage bulbs, the enclosure 112 may have a form factor that corresponds to the size and shape of a traditional bulb and the enclosure 112 may be transparent such that the glowing optic element 200 is visible through the enclosure 112. The enclosure 112 may also be made of a transparent colored material.

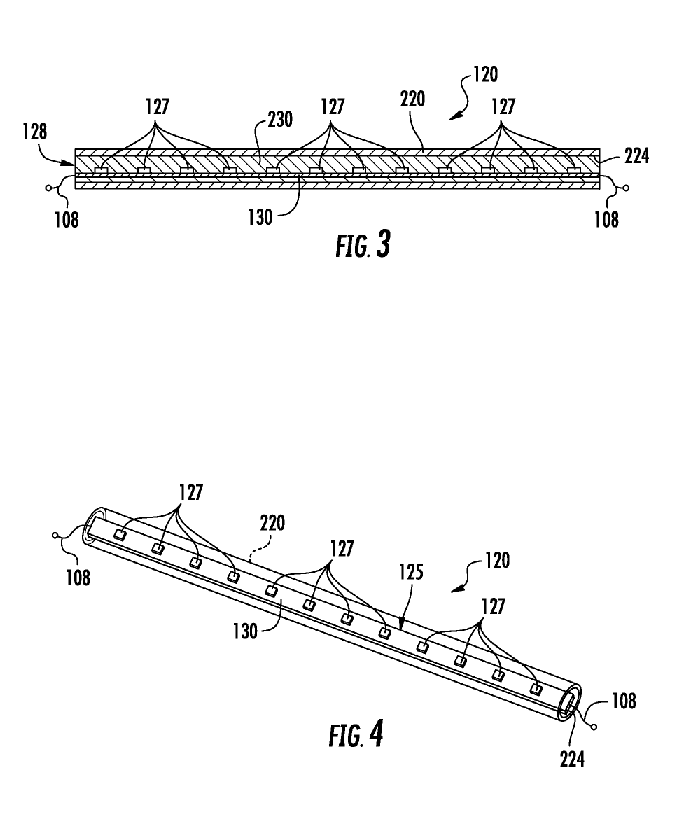

The LED lamp is shown comprising a LED assembly 120 provided with light emitting LEDs and/or LED packages 127 (see, for example, FIGS. 3 and 4). Multiple LEDs 127 may be used together, forming an LED array 128. The LEDs 127 may be spaced from one another any suitable distances and the LED array 128 may comprise any number or types of LEDs. The LEDs 127 can be mounted on or fixed within the lamp in various ways. In at least some example embodiments, a LED board 130 may be used to support the LEDs 127 and to form part of the electrical path to the LEDs. In one preferred embodiment the LED board 130 may comprise a transparent member such as glass or sapphire board such that the board does not block light emitted from the LEDs 127 and is substantially invisible during operation of the lamp. In other embodiments LED board 130 may comprise PCB, MCPCB, flex circuit, lead frame structure, flexible PCB or other similar structure. The LEDs 127 may comprise one or more LED dies disposed in an encapsulant such as silicone, and LEDs which may be encapsulated with a phosphor to provide local wavelength conversion. A wide variety of LEDs and combinations of LEDs may be used.

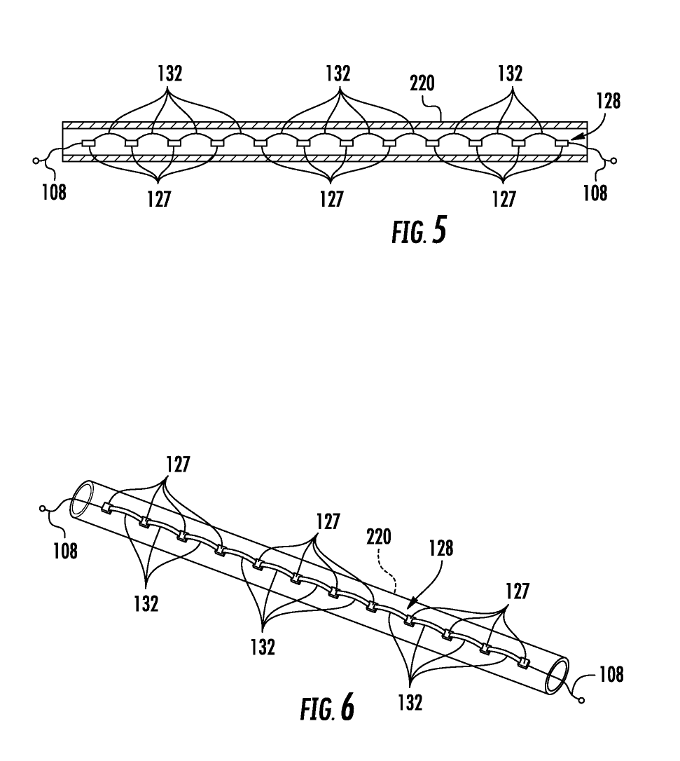

Referring to FIGS. 5 and 6, in some embodiments the LEDs 127 may not be mounted on a separate board that physically supports the LEDs. Rather the LED array 128 comprises LEDs 127 that are connected together by electrical connectors 132 which provide the necessary physical support to connect the LEDs 127 to one another during assembly of the LED array 128 in addition to providing the electrical connection to the LEDs. In one embodiment, the electrical connectors 132 comprise wirebonds where the wirebonds are made between the anodes and cathodes on the LEDs 127 and provide the electrical connection between the LEDs 127 and power supply to provide critical current to power the LEDs. While wirebonds are disclosed as an example of the electrical connector 132 between the LEDs 127, other methods and devices for making the electrical connection between the LEDs may also be used.

In some embodiments the LEDs 127 used in the formation of the LED array 128 may comprise LED chips having the anode and cathode terminals on the top of the chip where the electrical connector 132 extends from the top of one chip to the top of the adjacent chip. Suitable chips may be the CREE® TR LED chips, the CREE® TR-M LED chips, sapphire chips, or the like. While specific LED chips are identified, any suitable LED may be used. In other embodiments, LEDs 127 having top and bottom anodes and cathodes, may be assembled into a self-supporting LED array as described herein where the electrical connector 132 such as wirebonds make the electrical connection between the tops and bottoms of the chips. Suitable chips may be the CREE® RT LED chips. In another embodiment, flip-chip LED chips may be used where the LED chip has an anode and a cathode formed on the bottom thereof.

In the various embodiments described herein the LED array 128 may be bent into a variety of three-dimensional shapes at the electrical connectors 132 or at the board 130 if, for example, a flex circuit or metal core PCB is used to form the array 128. A three-dimensional shape as used herein means that the LED array may be formed into a shape where at least some of the LEDs 127 are disposed in different planes than other ones of the LEDs 127. For example, the LED array 128 may be formed to have a cylindrical or circular shape, a helical shape, a rectangular shape or other regular or irregular shapes. The LED array 128 may also be used as a linear string where all of the LEDs are in a single plane.

With respect to the features of the LED assembly and related electronic described herein with various example embodiments of a lamp, the features can be combined in various ways. The embodiments shown and described herein are examples only and are intended to be illustrative of various design options for a LED lighting system.

LEDs and/or LED packages used with an embodiment of the invention and can include light emitting diode chips that emit different hues of light that, when mixed, are perceived in combination as white light. Phosphors can be used as described to add yet other colors of light by wavelength conversion. For example, blue or violet LEDs can be used in the LED assembly of the lamp and the appropriate phosphor can be in any of the ways mentioned above. LED devices can be used with phosphorized coatings packaged locally with the LEDs or with a phosphor coating the LED die as previously described. For example, blue-shifted yellow (BSY) LED devices, which typically include a local phosphor, can be used with a red phosphor on or in the optically transmissive enclosure or inner envelope to create substantially white light, or combined with red emitting LED devices in the array to create substantially white light. LEDs 127 may be individually encapsulated, each in a package with its own lens. Such embodiments can produce light with a CRI of at least 70, at least 80, at least 90, or at least 95.

A lighting system using the combination of BSY and red LED devices referred to above to make substantially white light can be referred to as a BSY plus red or “BSY+R” system. In such a system, the LED devices used include LEDs operable to emit light of two or more different colors. A further detailed example of using groups of LEDs emitting light of different wavelengths to produce substantially while light can be found in issued U.S. Pat. No. 7,213,940, which is incorporated herein by reference.

With the embodiments shown herein, as with many other embodiments of the invention, the term “electrical path” can be used to refer to the entire electrical path to the LEDs 127, including an intervening power supply disposed between the electrical connection that would otherwise provide power directly to the LEDs and the LEDs, or it may be used to refer to the connection between the mains and all the electronics in the lamp, including the power supply. The term may also be used to refer to the connection between the power supply and the LEDs.

A base 102 may be connected to the enclosure 112 where the base functions as the physical connector to connect the lamp 100 to a corresponding socket and forms part of the electrical path to the LEDs 127. The base 102 may comprise an Edison base with an Edison screw 103 comprising threads that engage a standard Edison socket such that the base 102 may be screwed into the socket in the same manner as a traditional bulb having an Edison screw. Depending on the embodiment, other base configurations are possible to make the electrical connection such as other traditional-style bases. For example, a bayonet-style connector may be used that may be connected to a bayonet-style socket as previously described. The bayonet, Edison or other connector provides the physical connection between the lamp 100 and a fixture and forms part of the electrical path to the LEDs 127. The base 102 may be connected directly to the optically transparent enclosure 112 by adhesive, mechanical connector, welding, separate fasteners or the like.

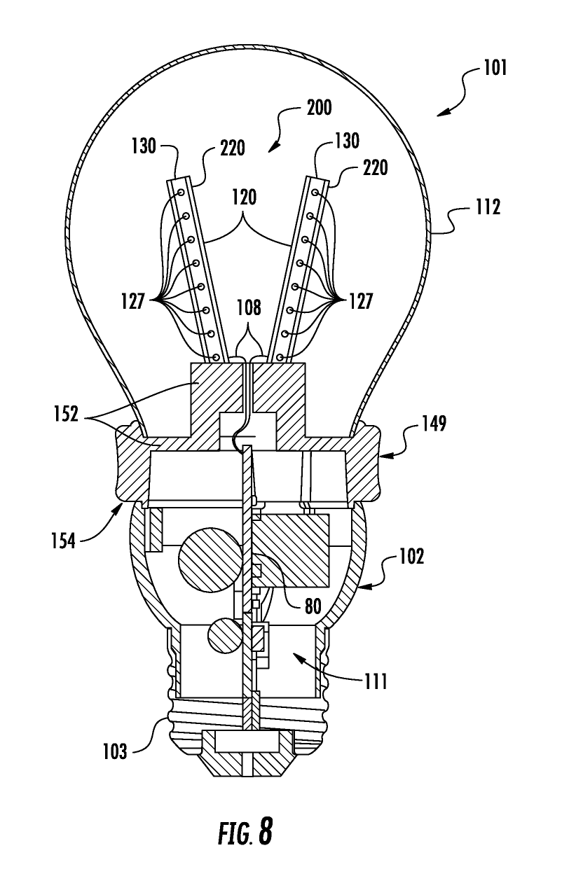

The base 102 defines an internal cavity 111 (FIGS. 2 and 8) for receiving the electronics 110 of the lamp including the power supply and/or drivers or a portion of the electronics for the lamp. The lamp electronics 110 are electrically coupled to the Edison screw 103 such that the electrical connection may be made from the Edison screw 103 to the lamp electronics 110. The lamp electronics may be mounted on a printed circuit board 80 which includes the power supply, including large capacitor and EMI components that are across the input AC line along with the driver circuitry as described herein. The base may be potted to protect and isolate the lamp electronics 110. Electrical conductors 108 run between the lamp electronics 110 and the LEDs 127 to carry both sides of the supply to provide critical current to the LEDs 127.

In some embodiments, the lamp electronics 110 comprise a driver and/or power supply. Base 102 may include the power supply or driver and form all or a portion of the electrical path between the mains and the LEDs 127. Suitable power supplies and drivers are described in U.S. patent application Ser. No. 13/462,388 filed on May 2, 2012 and titled “Driver Circuits for Dimmable Solid State Lighting Apparatus” which is incorporated herein by reference in its entirety; U.S. patent application Ser. No. 12/775,842 filed on May 7, 2010 and titled “AC Driven Solid State Lighting Apparatus with LED String Including Switched Segments” which is incorporated herein by reference in its entirety; U.S. patent application Ser. No. 13/192,755 filed Jul. 28, 2011 titled “Solid State Lighting Apparatus and Methods of Using Integrated Driver Circuitry” which is incorporated herein by reference in its entirety; U.S. patent application Ser. No. 13/339,974 filed Dec. 29, 2011 titled “Solid-State Lighting Apparatus and Methods Using Parallel-Connected Segment Bypass Circuits” which is incorporated herein by reference in its entirety; U.S. patent application Ser. No. 13/235,103 filed Sep. 16, 2011 titled “Solid-State Lighting Apparatus and Methods Using Energy Storage” which is incorporated herein by reference in its entirety; U.S. patent application Ser. No. 13/360,145 filed Jan. 27, 2012 titled “Solid State Lighting Apparatus and Methods of Forming” which is incorporated herein by reference in its entirety; U.S. patent application Ser. No. 13/338,095 filed Dec. 27, 2011 titled “Solid-State Lighting Apparatus Including an Energy Storage Module for Applying Power to a Light Source Element During Low Power Intervals and Methods of Operating the Same” which is incorporated herein by reference in its entirety; U.S. patent application Ser. No. 13/338,076 filed Dec. 27, 2011 titled “Solid-State Lighting Apparatus Including Current Diversion Controlled by Lighting Device Bias States and Current Limiting Using a Passive Electrical Component” which is incorporated herein by reference in its entirety; and U.S. patent application Ser. No. 13/405,891 filed Feb. 27, 2012 titled “Solid-State Lighting Apparatus and Methods Using Energy Storage” which is incorporated herein by reference in its entirety.

The AC to DC conversion may be provided by a boost topology to minimize losses and therefore maximize conversion efficiency. The boost supply is connected to high voltage LEDs operating at greater than 200 V. Examples of boost topologies are described in U.S. patent application Ser. No. 13/462,388, entitled “Driver Circuits for Dimmable Solid State Lighting Apparatus”, filed on May 2, 2012 which is incorporated by reference herein in its entirety; and U.S. patent application Ser. No. 13/662,618, entitled “Driving Circuits for Solid-State Lighting Apparatus with High Voltage LED Components and Related Methods”, filed on Oct. 29, 2012 which is incorporated by reference herein in its entirety. Other embodiments are possible using different driver configurations or a boost supply at lower voltages.

In some embodiments the driver circuit may have an input configured to be coupled to a power source, such as a phase cut dimmer, that provides a varying voltage waveform. The driver may include electromagnetic interference suppression electronics to reduce noise in the driver. One such suitable electronics is shown and described in U.S. patent application Ser. No. 14/284,643, entitled “Lighting apparatus with Inductor Current Limiting for Noise reduction”, filed on May 22, 2014, which is incorporated by reference herein in its entirety.

In the embodiments of FIGS. 1 and 2 heat is dissipated from the LED assemblies 120 through the optically transmissive enclosure 112 via the medium 136 that fills the enclosure 112. The medium 136 that fills the enclosure may be a gas. In one embodiment the gas comprises air. In other embodiments the gas may comprise a gas or combination of gasses with high thermally conductive properties. Examples of suitable gases include helium, hydrogen, and additional component gasses, including a chlorofluorocarbon, a hydrochlorofluorocarbon, difluoromethane and pentafluoroethane. It should also be noted that a gas used for cooling a lamp need not be a gas at all times. Materials which change phase can be used and the phase change can provide additional cooling. For example, at appropriate pressures, alcohol or water could be used in place of or in addition to other gasses. Using only the medium 136 and the enclosure 112 to dissipate heat from the LEDs 127 may limit the amount of heat dissipated from the lamp such that in some embodiments the lamp may be used in lower brightness applications such as candelabra, 40 W and 60 W applications.

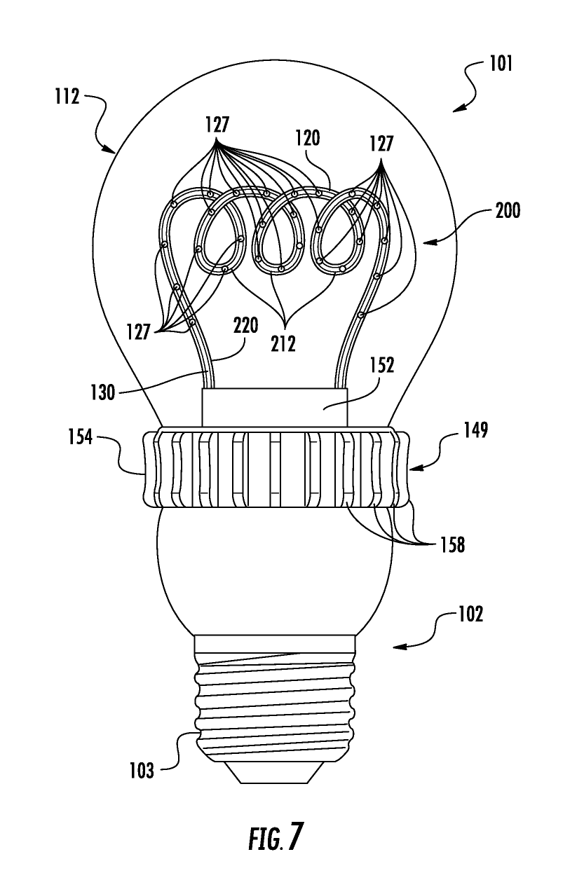

Referring to FIGS. 7 and 8, in some embodiments it may be desirable to increase the thermal dissipative properties of the lamp by thermally coupling the LED assemblies 120 to a heat sink. The heat sink 149 comprises a heat conducting portion 152 and a heat dissipating portion 154. In one embodiment the heat sink 149 is made as a one-piece member of a thermally conductive material such as aluminum, zinc or the like. The heat sink 149 may also be made of multiple components secured together. Moreover, the heat sink 149 may be made of any thermally conductive material or combinations of thermally conductive materials. In some embodiments a heat sink structure may not be used.

The heat conducting portion 152 is dimensioned and configured to make good thermal contact with the LED assembly 120 such that heat generated by the LED assembly 120 may be efficiently transferred to the heat sink 149. The heat conducting portion 152 is in good thermal contact with the heat dissipating portion 154 such that heat conducted away from the LED assembly 120 by the heat conducting portion 152 may be efficiently dissipated from the lamp 101 by the heat dissipating portion 154. The heat dissipating portion 154 extends from the interior of the lamp to the exterior of the lamp 100 such that heat may be dissipated from the lamp to the ambient environment. A plurality of heat dissipating members 158 may be formed on the exposed portion to facilitate the heat transfer to the ambient environment. In one embodiment, the heat dissipating members 158 comprise a plurality fins that extend outwardly to increase the surface area of the heat dissipating portion 154. The heat dissipating portion 154 and fins 158 may have any suitable shape and configuration. The base 102 may be connected to the heat sink 149 and the heat sink may be attached to the enclosure 112.

Referring again to FIGS. 1 and 2, the lamp 100 comprises an optic element 200 that extends from adjacent the base 102 and that is configured and positioned in the enclosure 112 such that it is in approximately the same position as the glowing filament of a traditional incandescent bulb. The optic element 200 may be configured to have a visual appearance that is similar to or mimics the glowing filament of an incandescent bulb.

The optic element 200 comprises at least one LED assembly 120 as described herein that extends from a support element 201. In some embodiments the optic element 200 comprises multiple LED assemblies 120. In one embodiment the support element 201 is positioned adjacent the bottom edge of the enclosure 112 to separate the interior space of the enclosure 112 from the base 102. The support element 201 may comprise a glass, acrylic or plastic. In one embodiment the support element 201 is transparent. In one embodiment the support element 201 may be a solid piece of material that has a base portion 202 that divides the base 102 from the enclosure 112 and a stem 204 that extends into the interior space of the enclosure 112. The optic element 200 is connected to the support element 201 such that the optic element is supported in the desired position in the enclosure 112. Electrical conductors such as wires 108 extend from the lamp electronics 110, through the support element 201 and to the LED assembly 120 to form part of the electrical path to the LED assembly to deliver critical current to the LEDs 127. In one embodiment the wires 108 not only form part of the electrical path to the LEDs 127 but also physically support the LED assemblies 120 in the desired position in the enclosure. In other embodiments, the LED assemblies 120 may be physically supported on separate members from the conductors 108 such as additional wires or rods 208 that are not in the electrical path.

Referring to FIGS. 3 and 4, the LED assembly 120 comprises a transparent tube 220 that retains the LEDs 127 and board 130 or conductors 132. The transparent tube 220 may comprise glass, sapphire, plastic or other transparent material. In one embodiment the tube is clear. While a single LED 127 may be mounted in the tube 220 in most embodiments a plurality of LEDs 127 may be provided in an array 128, as previously described, that extends along the length of the tube 220. The LEDs 127 in the tube 220, when energized to emit light, provide a light distribution that has a visual appearance that is similar to a glowing incandescent filament. In some embodiments the tube 220 may be separately attached to the support element 201 such that the tube 220 and the support element 201 are physically connected to one another. Such an arrangement may be used in addition to or in place of using the wires 108 that form part of the electrical path to the LEDs.

The tube 220 is formed with a hollow interior 224 that receives the LED array 128 such that the tube 220 surrounds the LED array. The term “tube” as used herein refers to any optically transmissive, member that has a relatively thin-walled construction with a hollow interior defining a space for receiving the LED array such that light emitted by the LEDs 127 is transmitted through the tube. While a substantially cylindrical tube 220 is illustrated the tube may have other shapes and in cross-section the tube may be triangular, rectangular, faceted or have other regular or irregular shapes. Moreover, the tube may be curved along its length such that the tube 220 and the LED string may have a curved shape inside of the lamp as shown for example in FIG. 7 where the LED assembly 120 is formed to have a spiral shape.

The tube 220 is filled with a fill material that may be selected based on the desired properties or attributes of the LED assembly 120. Referring to FIG. 3, in one embodiment the fill material comprises an encapsulant 230 (represented by hatched lines in the figures) where interior space 224 of the tube 220 is filled with the encapsulant 230 such as silicone. The encapsulant 230 may be clear such that the encapsulant is used primarily to protect the LEDs 127 and does not affect the light emitted by LEDs 127. Using a tube 220 to surround the LED array 128 provides a uniform space for receiving the encapsulant 230 such that the layer of the encapsulant over the LEDs 127 is uniform over the length of the LED array 128. The LED array 128 may be inserted into the tube 220 and the encapsulant 230 may be added to the tube as a liquid and cured to create the LED assembly 120.

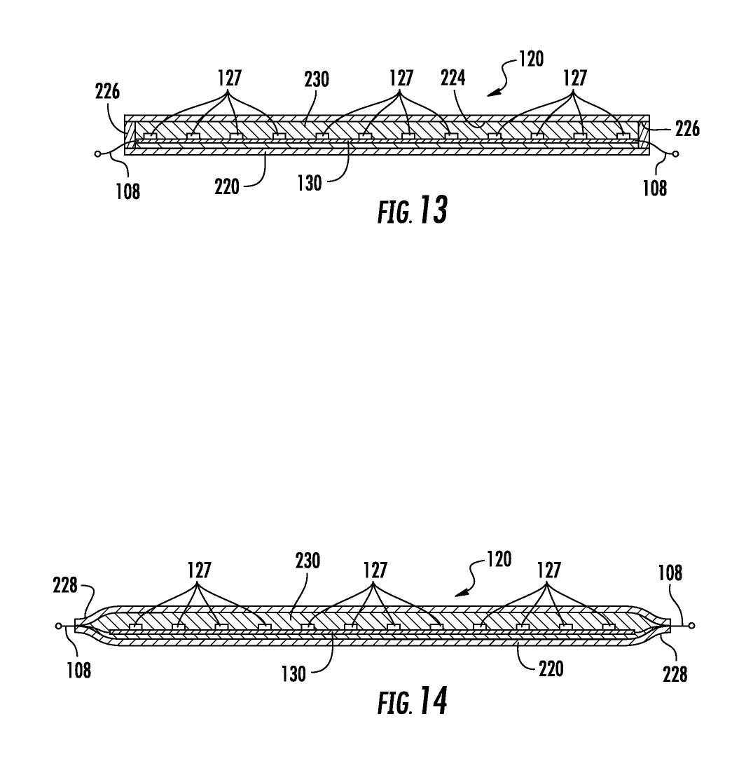

In some embodiments the encapsulant may be a curable encapsulant such as silicone or an optical epoxy while in other embodiments the encapsulant may be an optically clear fluid such as an oil. For encapsulants such as silicone and epoxies the encapsulant may be cured such that the ends of the tube 220 may be left open. For encapsulants such as oils or other optical fluids the ends of the tube may be closed to retain the fill material in the tube. In one embodiment a separate cap 222 may be secured to each end of the tube 220 by adhesive, mechanical connector, fusing or the like as shown in FIG. 12. The caps 222 may be made of an optically transmissive material. In other embodiments the ends of the tube may be sealed using a plug 226 that is inserted into the ends of the tube as shown in FIG. 13. The plug 226 may be a mechanical plug that is secured to each end of the tube by adhesive, mechanical connector, fusing or the like or the plug may be a plug of silicone or epoxy or the like. In some embodiments, for example with a glass or plastic tube, the ends of the tube may be heated and fused to seal the fill material in the tube as shown at 228 in FIG. 14. The conductors 108 may extend from the LED array through the caps 222, plugs 226 or the tube 220 to the exterior of the LED assembly.

In another embodiment as shown in FIG. 9 the fill material may comprise an encapsulant 230 and phosphor 240 (represented by dark circles) where the phosphor may be dispersed throughout the layer of encapsulant 230. The phosphor 234 can be used as described for wavelength conversion. For example, blue or violet LEDs can be used in the LED assembly of the lamp and the appropriate phosphor can be applied to the encapsulant to obtain a desired light color. For example, blue-shifted yellow (BSY) LED devices can be used with a red phosphor to create substantially white light.

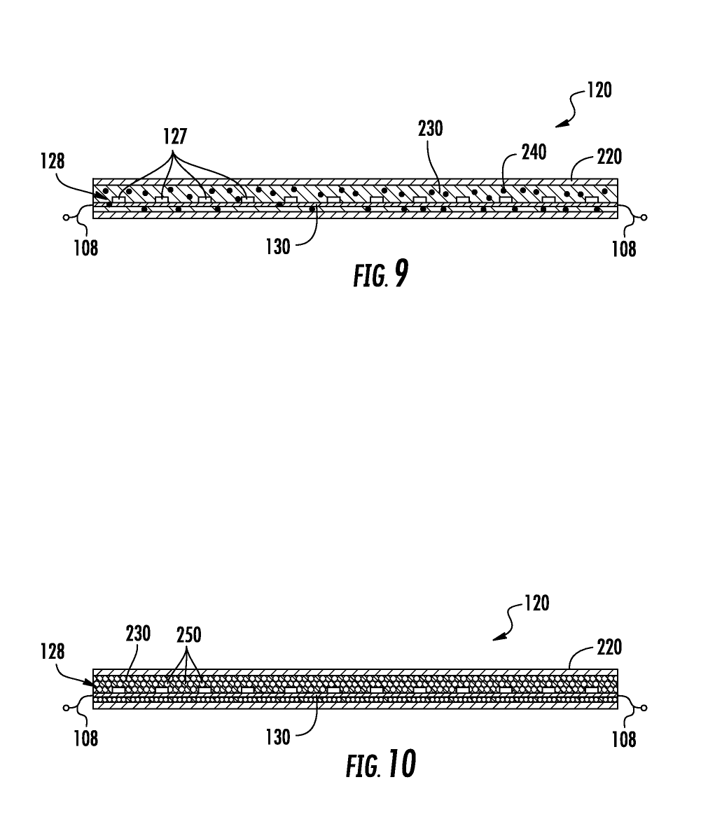

In another embodiment as shown in FIG. 10 the fill material may comprise an encapsulant 230 and a thermal fill 250 (represented by open circles) where the thermal fill 250 comprises a thermally conductive material used to provide better heat transfer from the LED array 128 to the gas in the enclosure 112 or from the LED array 128 to the heat sink 149. The thermal fill may comprise a thermally conductive material that has a high thermal conductivity and may comprise a particulate that is dispersed in the encapsulant 230. In one embodiment the index of refraction of the thermal fill 250 is selected to be closely matched to the index of refraction of the encapsulant 230. For example, for an encapsulant with a relatively lower index of refraction (e.g. 1.4) the thermal fill 250 may have a similarly lower index of refraction such as flourides, calcium, magnesium or zinc while an encapsulant with a relatively higher index of refraction (e.g. 1.5) the thermal fill may have a similarly high index of refraction such as SiO2, while an encapsulant with an even higher index of refraction (e.g. 1.7) the thermal fill may have a similarly high index of refraction such as alumina or ceramic particles. The examples provided above are for explanation purposes and the actual thermal fill and index of refraction may vary. By matching the index of refraction of the thermal fill to the index of refraction of the encapsulant the fill material will not affect the emitted light. Because the thermal fill 250 functions to transmit heat away from the LEDs 127 it may be desirable to pack the thermal fill 250 close together in the encapsulant using the encapsulant 230 primarily as a binder to hold the thermal fill 250 together in the tube 220. In one embodiment the thermal fill 250 may constitute between 70% and approaching 100% by weight of the fill material and approximately 50% by volume. The thermal fill 250 may approach 100% by weight of the fill material because some thermally conductive materials are significantly denser than the silicone or other encapsulant. The greater the relative amount of thermal fill and the more densely packed the thermal fill, the better and more efficient the heat transfer from the LEDs 127.

In one embodiment the thermal fill 250 and encapsulant 230 may be mixed and introduced into the tube 220 as a liquid and cured. In other embodiments the thermal fill 250 may be introduced into the tube 220 as a particulate such as a powder and the encapsulant 230 injected into the tube 220 under pressure and cured.

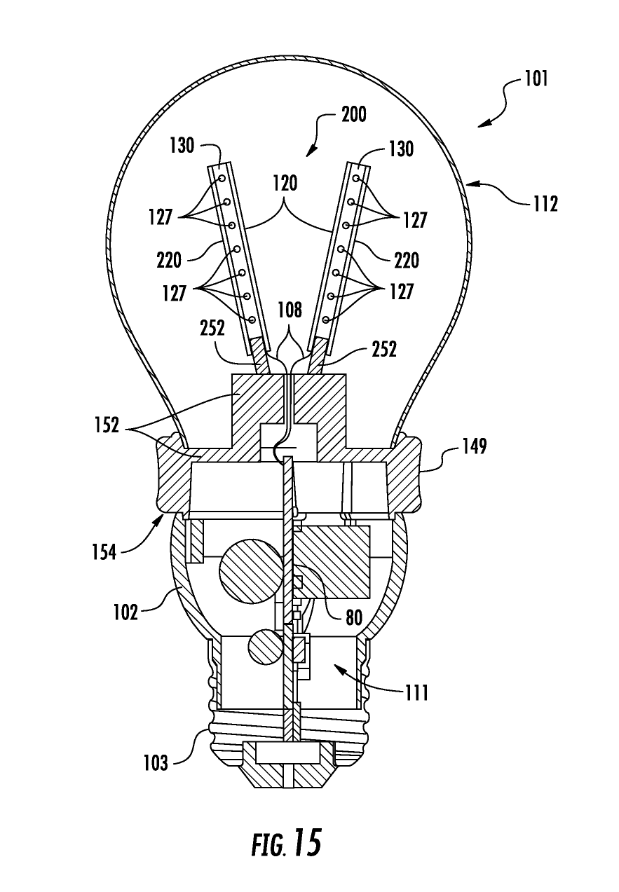

In embodiments where the heat transfer is to take place primarily between the tube 220 and the gas or other media 136 in the enclosure 112, the tube 220 may be supported in any suitable manner such as described with respect to FIGS. 1 and 2 and may be supported on a support member with low thermally conductive properties. In embodiments where the heat transfer is to take place between the fill material and a physical heat sink (such as shown in FIGS. 7, 8 and 15), the tube 220 may be supported by the heat sink 149 such that the fill material is thermally coupled to the heat sink. For example, as shown in FIGS. 7 and 8 the LED assembly 120 may be secured directly to the heat sink 149 by adhesive, physical connectors, fusing or the like where the thermal fill material is in physical contact with the heat sink 149. An intervening layer or layers may be provided between the fill material and heat sink such as a thermal epoxy provided a heat transfer path is created between the fill material and the heat sink. In some embodiments a separate heat conducting member 252 such as an aluminum support may physically connect and thermally couple the heat sink 149 to the thermal fill material 250 as shown in FIG. 15.

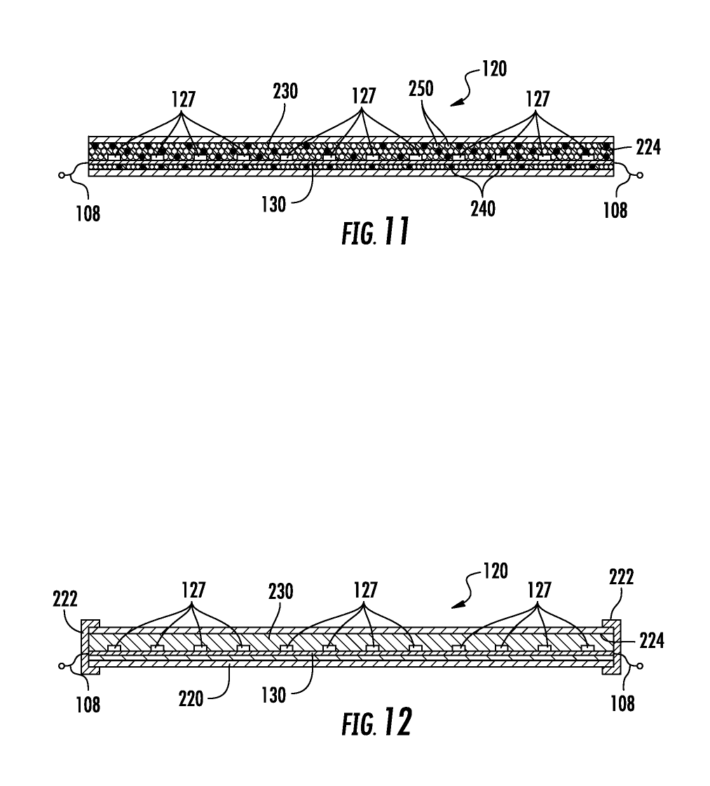

In other embodiments the fill material may comprise an encapsulant 230, a phosphor 240, for providing wavelength conversion and a thermal fill material 250 as shown in FIG. 11.

Using the tube as described herein to hold the encapsulant, the encapsulant and phosphor, the encapsulant and thermal fill material or the encapsulant, phosphor and thermal fill material allows the fill material to be applied evenly over the LED assembly such that the thickness of the layer of material applied over LEDs may be controlled and unintended variations in the thickness may be eliminated.

A single LED assembly 120 may be used to make the optic element 200 or the optic element 200 may be made of a plurality of separate LED assemblies 120. Light generated by the LEDs 127 is transmitted through the fill material and the tube 220 and is emitted from the optic element such that it is visible from the exterior of the lamp through the enclosure 112. The optic element 200 is configured such that the light is emitted in a pattern that visually appears similar to or that mimics the light as it appears from the glowing filament of a traditional incandescent bulb. The tube may comprise a notched, roughened or irregular surface, or other surface treatment that causes the light to be emitted from the optic element 200 in random directions such that the light undergoes diffusion or scattering. The surface treatment of the tube 220 may be provided by scratching, etching or otherwise treating the tube. Alternatively the surface treatment of the tube 220 may be provided during formation of the tube such as during a molding process of the tube.

In one embodiment, the LEDs 127 may be controlled to control the color of the light emitted from the optic element 200. In one embodiment, the light is controlled such the light emitted from the optic element 200 may be, under certain operating conditions, red/orange/red-orange in color. Software may be used to shunt current to and from selected LEDs 127 to control the color of the light emitted by the LED assembly 120. In one embodiment, the color of the light may be changed from essentially white light to red/orange/red-orange light when a user lowers the current delivered to the LED power supply 110. In one embodiment a dimmer switch may be provided to control the current delivered to the LED power supply. The dimmer switch may be provided in the electrical path and may be part of the fixture with which the lamp 100 is used or it may be located remotely from the fixture such as on a wall as is typical of a standard light switch. When the current delivered to the LED power supply 110 falls below a predetermined value, the power supply software shunts the current to desired LEDs to change the color of the light emitted from the LED assembly 120. By making the color change to red/orange/red-orange when the current is lowered (such as in response to a user controlled dimmer switch) the optic element 200 can be made to glow red-orange to simulate the look of a dimmed incandescent bulb. In some embodiments, the color may change as the current passes predetermined levels. For example, at a first current level the color may change to red-orange and at a second current level the color may change to orange and at a third current level the color may change to white. As the current level rises the lumens output by the LEDs 127 may also increase such that the brightness of the lamp increases as the color changes. The dimmable, color changing arrangement described above may be used with any of the embodiments described herein. In some embodiments color control is used and RF control circuitry for controlling color may also be used in some embodiments. The lamp electronics may include light control circuitry that controls color temperature of any of the embodiments disclosed herein in accordance with user input such as disclosed in U.S. patent application Ser. No. 14/292,286, filed May 30, 2014, entitled “Lighting Fixture Providing Variable CCT” by Pope et al. which is incorporated by reference herein in its entirety.

In the embodiment of FIGS. 1 and 2 the optic element 200 is formed to have plural linear LED assemblies 120 that are disposed in the enclosure 112 to simulate the look of filaments as found in traditional incandescent bulbs. The LED assemblies 120 may extend generally parallel to the longitudinal axis of the lamp to simulate a cage style filament as found in traditional incandescent bulbs. FIG. 7 shows the optic element 200 formed to simulate a multiple coil style filament where the optic element 200 is formed into a series of loops 212 disposed at the approximate center of the enclosure 112. FIG. 2 shows the optic element 200 formed to simulate a traditional incandescent bulb where the optic element is a linear member located at the approximate center of the enclosure 112 arranged transverse to the longitudinal axis of the lamp. The optic element may have other traditional shapes, such as spiral, “hairpin”, or other non-traditional shapes.

In some embodiments wireless a module 600 may be provided in the lamp (FIG. 2) for receiving, and/or transmitting, a radio signal or other wireless signal between the lamp and a control system and/or between lamps. The wireless module and related smart technologies may be used in any embodiments of the lamp as described herein. The wireless module 600 may convert the radio wave to an electronic signal that may be delivered to the lamp electronics 110 for controlling operation of the lamp. The wireless module may also be used to transmit a signal from the lamp. In various embodiments described herein various smart technologies may be incorporated in the lamps as described in the following applications “Solid State Lighting Switches and Fixtures Providing Selectively Linked Dimming and Color Control and Methods of Operating,” application Ser. No 13/295,609, filed Nov. 14, 2011, which is incorporated by reference herein in its entirety; “Master/Slave Arrangement for Lighting Fixture Modules,” application Ser. No. 13/782,096, filed Mar. 1, 2013, which is incorporated by reference herein in its entirety; “Lighting Fixture for Automated Grouping,” application Ser. No. 13/782,022, filed Mar. 1, 2013, which is incorporated by reference herein in its entirety; “Multi-Agent Intelligent Lighting System,” application Ser. No. 13/782,040, filed Mar. 1, 2013, which is incorporated by reference herein in its entirety; “Routing Table Improvements for Wireless Lighting Networks,” application Ser. No. 13/782,053, filed Mar. 1, 2013, which is incorporated by reference herein in its entirety; “Commissioning Device for Multi-Node Sensor and Control Networks,” application Ser. No. 13/782,068, filed Mar. 1, 2013, which is incorporated by reference herein in its entirety; “Wireless Network Initialization for Lighting Systems,” application Ser. No. 13/782,078, filed Mar. 1, 2013, which is incorporated by reference herein in its entirety; “Commissioning for a Lighting Network,” application Ser. No. 13/782,131, filed Mar. 1, 2013, which is incorporated by reference herein in its entirety; “Ambient Light Monitoring in a Lighting Fixture,” application Ser. No. 13/838,398, filed Mar. 15, 2013, which is incorporated by reference herein in its entirety; “System, Devices and Methods for Controlling One or More Lights,” application Ser. No. 14/052,336, filed Oct. 10, 2013, which is incorporated by reference herein in its entirety; and “Enhanced Network Lighting,” application Ser. No. 61/932,058, filed Jan. 27, 2014, which is incorporated by reference herein in its entirety.

Although specific embodiments have been illustrated and described herein, those of ordinary skill in the art appreciate that any arrangement, which is calculated to achieve the same purpose, may be substituted for the specific embodiments shown and that the invention has other applications in other environments. This application is intended to cover any adaptations or variations of the present invention. The following claims are in no way intended to limit the scope of the invention to the specific embodiments described herein.

1. A LED lamp comprising;
an enclosure;
an optic element in the enclosure comprising an LED array for emitting light when energized through an electrical path and a tube surrounding the LED array and a fill material in the tube.

2. The LED lamp of claim 1 wherein a base is connected to the enclosure, the base being in the electrical path.

3. The LED lamp of claim 1 wherein the fill material comprises an optically transparent encapsulant.

4. The LED lamp of claim 3 wherein the encapsulant comprises silicone.

5. The LED lamp of claim 1 wherein the optic element is configured to visually appear like one of a cage, a loop, and a linear filament.

7. The LED lamp of claim 1 wherein the fill material comprises an encapsulant and a phosphor.

8. The LED lamp of claim 1 wherein the fill material comprises an encapsulant and a thermally conductive material.

9. The LED lamp of claim 1 wherein the fill material comprises an encapsulant, a thermally conductive material and a phosphor.

10. The LED lamp of claim 1 wherein the LED array comprises a LED mounted on a transparent substrate.

11. The LED lamp of claim 1 wherein the LED array comprises a plurality of LEDs connected by wirebonds.

12. The LED lamp of claim 1 wherein the fill material comprises a thermal powder and an encapsulant.

13. The LED lamp of claim 1 wherein the fill material is exposed at an end of the tube.

14. The LED lamp of claim 1 wherein the fill material is thermally coupled to a heat sink.

15. A LED lamp comprising;
a base;
an enclosure connected to the base;
an optic element in the enclosure comprising an LED assembly comprising a LED array for emitting light when energized through an electrical path and a tube surrounding the LED array and a fill material filling the tube.

16. The LED lamp of claim 15 wherein the fill material comprises an optically transparent encapsulant.

17. The LED lamp of claim 15 wherein the optic element is configured to visually appear like one of a cage, a loop, and a linear filament.

18. The LED lamp of claim 15 wherein the fill material comprises at least one of an encapsulant, a phosphor and a thermally conductive material.

19. The LED lamp of claim 15 wherein the LED assembly comprises a LED mounted on a substrate.

20. The LED lamp of claim 19 wherein the substrate is transparent.
